(19) United States
(12) Patent Application Publication
(10) Pub. No.: US 2026/0088804 A1
(43) Pub. Date: Mar. 26, 2026

(54) Early Out Filter Accelerator Systems and Methods

(71) Applicant: Apple Inc., Cupertino, CA (US)

(72) Inventors: Brian D Clark, San Jose, CA (US); Aniruddha Satoskar, Round Rock, TX (US); Brendan C Larks, San Diego, CA (US); Hanchi Chen, Mountain View, CA (US); Leonardo Rub, Sunnyvale, CA (US); Peter C Eastty, San Francisco, CA (US)

(21) Appl. No.: 19/002,439

(22) Filed: Dec. 26, 2024

Related U.S. Application Data
(60) Provisional application No. 63/699,685, filed on Sep. 26, 2024.

(51) Int. Cl. H03H 17/02; G10K 11/178

(52) U.S. Cl. CPC H03H 17/0202; G10K 11/17853

(57) ABSTRACT

An electronic device may include one or more filters arranged to filter an input signal and circuitry that generates a filtered output corresponding to an application of the one or more filters on the input signal. The circuitry may generate the filtered output based on determination of a multiplication factor based on respective coefficients of filter components of the one or more filters, determination of an addition offset based on respective states of the one or more filters, and a combination of the multiplication factor, the addition offset, and the input signal.

### CROSS-REFERENCE TO RELATED APPLICATIONS

This application claims priority to U.S. Provisional Application No. 63/699,685, filed Sep. 26, 2024, which is incorporated by reference herein in its entirety.

### BACKGROUND

The present disclosure relates generally to digital data filters and, more specifically, techniques for calculating filter outputs with improved (e.g., reduced) latency.

In general, electronic devices utilize filters, such as finite impulse response (FIR) filters or other linear data filters, to shape or modify data signals such as audio, video, and/or communication signals. Indeed, filters may be implemented digitally, such as to operate on a digital signal, and/or via analog circuitry for operating on analog signals. Furthermore, filters are used for a number of reasons such as improving the clarity of the signal being modified, adding functionality to the electronic device by performing an augmentation to the signal, and/or performing statistical analysis of the signal being filtered, to name few.

In some scenarios, the operating costs associated with filtering may be prohibitive and/or reduce the efficacy of the electronic device. For example, audio signals may be filtered to augment an audio output of an electronic device for improved sound quality and/or to implement features such as noise canceling, and such implementations may be subject to timing limitations (e.g., latency requirements).

### SUMMARY

This disclosure is generally directed to digital data filters and, more specifically, filter architectures that improve operational efficiency such as reduced latency. In general, electronic devices utilize filters to shape or modify signals such as audio, video, and/or communication signals. However, such filters may exhibit trades offs between operating costs such as power consumption (e.g., associated with a processing rate) and performance such as latency and signal quality. As such, embodiments of the present disclosure include techniques for improved calculation of a filtered signal to provide the filter output with a reduced latency relative to linear and/or parallel processing of filter stages, while maintaining the signal quality and/or processing rate.

In some embodiments, filter circuitry may include a filter block with a number of filter stages, each stage having one or more filter components to form a linear time-invariant filter or system of filters. The filter components may include multipliers, adders, phase delays (e.g., transfer functions), and/or sub-filters (e.g., known groupings of components), such as all-pass filters, low-pass filters, high-pass filters, etc. Additionally, by defining coefficients and/or transfer functions of the filter components (e.g., multiplier coefficients), the input signal may be modified to achieve a desired result.

The filter circuitry may also include an early out block that computes an early out multiplier, based directly on the filter coefficients and/or transfer functions of the filter components, and an early out offset, indicative of the accumulated state of the filter block to directly calculate the filtered signal based on the input signal before or without evaluating the computations of the individual filter stages. In other words, the early out block may determine a filtered signal of the filter block without or prior to evaluation of the filter block. For example, the early out block may directly calculate the output of the filter by multiplying the filter input by an early out multiplier and adding an early out offset. Moreover, the multiply-add computation may generally be performed faster (e.g., in less computational cycles) than evaluation of the filter stages, thus providing a latency improvement.

This expedited calculation may be performed by exploiting properties of linear time-invariant filters to rearrange and factorize the effective processing of the filter block as a change to the input signal in combination with an effect of previous input signals. For example, the filter block may include phase shifts that effectively delay the data signal by one or more samples. By leveraging the effect of phase shifts (e.g., z-inverse functions), as delaying the flow of data, portions of the filter stages that rely upon phase delayed outputs of previous filter stages may be separated out from calculations that rely upon the current input signal. In other words, as the input signal will be delayed at certain filter components by a cycle, the effect of such components on the filtered signal for the current cycle (e.g., current sample of the input signal) will not be based on the input signal and may be precomputed based on the filter states of the previous input signal. As such, the early out offset may be precomputed (e.g., prior to receiving the current input signal) based on an aggregate of the filter states generated by the previous input signal and the filter coefficients. Furthermore, components of the filtered signal that do not cause a phase delay and/or are not blocked by a data path with a phase delay may be effectively combined to form a single multiplier (e.g., the early out multiplier) to be applied to the input signal.

As should be appreciated, the techniques discussed herein may be applicable in any suitable electronic device for use on any suitable digital data, such as audio data, image data, communications data, etc. Moreover, while audio signals are discussed herein as examples of data to be filtered, it should be appreciated that such is merely given as an example scenario where latency may be of particular interest. Furthermore, while the techniques discussed herein may be implemented to reduce latency associated with a digital filter, the embodiments discussed herein may also be applicable in scenarios where latency is not of principle concern and, thus, may be traded for other processing costs. For example, the early out computation may be performed while a processing rate or data rate is reduced, thus saving power while reducing or maintaining latency and/or increasing or maintaining signal quality.

### BRIEF DESCRIPTION OF THE DRAWINGS

Various aspects of this disclosure may be better understood upon reading the following detailed description and upon reference to the drawings in which:

FIG. 1 is a block diagram of an electronic device including filter circuitry, according to embodiments of the present disclosure;

FIG. 2 is a front view of a handheld device representing an example of the electronic device of FIG. 1, according to embodiments of the present disclosure;

FIG. 3 is a front view of another handheld device representing another example of the electronic device of FIG. 1, according to embodiments of the present disclosure;

FIG. 4 is a perspective view of a notebook computer representing an example of the electronic device of FIG. 1, according to embodiments of the present disclosure;

FIG. 5 illustrates front and side views of a wearable electronic device representing another example of the electronic device of FIG. 1, according to embodiments of the present disclosure;

FIG. 6 is a perspective view of an audio device representing an example of the electronic device of FIG. 1, according to embodiments of the present disclosure;

FIG. 7 is a perspective view of a headset representing an example of the electronic device of FIG. 1, according to embodiments of the present disclosure;

FIG. 8 is a block diagram of filter circuitry of FIG. 1, including a filter block, an early out block, and a dynamic adaptation block, according to embodiments of the present disclosure;

FIG. 9 is a schematic diagram of a portion of the filter circuitry of FIG. 8, including the filter block and the early out block, according to embodiments of the present disclosure;

FIG. 10 is a timing diagram comparing the processing time to output a filtered signal using linear processing versus early out processing, according to embodiments of the present disclosure;

FIG. 11 is a schematic diagram of an example filter block having multiple filter stages disposed in a direct form, according to embodiments of the present disclosure;

FIG. 12 is a schematic diagram of an example filter block having multiple filter stages disposed in a transpose form, according to embodiments of the present disclosure;

FIG. 13 is a schematic diagram of an example filter block forming a warped FIR filter separated into portions attributable to the current input signal and previous input signals, according to embodiments of the present disclosure;

FIG. 14 is an example early out computation corresponding to the warped FIR filter of FIG. 13, according to embodiments of the present disclosure;

FIG. 15 is a schematic diagram of an example filter block having a cascaded chain of filter stages presented with a graphical depiction of an example early out computation, according to embodiments of the present disclosure; and

FIG. 16 is a flowchart of an example process for implementing filter circuitry with an early out block to expedite calculation of a filtered signal, according to embodiments of the present disclosure.

### DETAILED DESCRIPTION OF SPECIFIC EMBODIMENTS

When introducing elements of various embodiments of the present disclosure, the articles “a,” “an,” and “the” are intended to mean that there are one or more of the elements. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features. Furthermore, the phrase A “based on” B is intended to mean that A is at least partially based on B. Moreover, the term “or” is intended to be inclusive (e.g., logical OR) and not exclusive (e.g., logical XOR). In other words, the phrase A “or” B is intended to mean A, B, or both A and B.

In general, electronic devices utilize filters, such as finite impulse response (FIR) filters or other linear and/or time-invariant filters to shape or modify signals such as audio, video, and/or communication signals. Indeed, filters may be implemented digitally, such as to operate on a digital signal, and/or via analog circuitry for operating on analog signals. Furthermore, filters are used for a number of reasons such as improving the clarity of the signal being modified, adding functionality to the electronic device by performing an augmentation to the signal, and/or performing statistical analysis of the signal being filtered, to name few. However, filters may incur operating costs such as power consumption and/or introduce latency in the signal being filtered and may be subject to space (e.g., physical footprint) constraints. In general, digital filters may be utilized over analog filters for decreased power consumption, decreased circuit footprint, and/or to implement additional features, such as programmable changes and/or adaptive feedback.

In the context of digital filters, tradeoffs may occur between the quality of the filter (e.g., effectiveness for the desired purpose), the latency of the filter, and/or the power consumption of the filter. For example, if a reduced power consumption is desired, the quality may decrease and/or the latency may increase, and if a reduced latency is desired, the power consumption may increase and/or quality may decrease. As should be appreciated, decreased power consumption may be of particular advantage in mobile devices, such as to increase a battery life of the electronic device. Moreover, a reduction in quality and/or an increase in latency may be undesirable or unacceptable depending on implementation. For example, audio signals may be filtered to augment an audio output of an electronic device for improved sound quality and/or to implement features such as noise canceling. In some embodiments, timing constraints may be implemented to ensure proper functionality. For example, an electronic device or system may perform noise canceling by receiving (e.g., via a microphone) ambient audio sounds, performing filtering of the ambient audio sounds, and outputting (e.g., via a speaker) a counteracting audio sound that (e.g., based on an inverted audio signal), when synchronized with the ambient audio sounds at a listening location (e.g., human ear) the ambient audio sounds are reduced or inaudible. However, timing the output of the counteracting audio sound to match the ambient audio sounds may constrain the timing available for filtering the ambient audio sounds and generating the counteracting audio sound. Indeed, time efficient calculation of a filter output (e.g., filtered signal) may be desired to meet system latency demands.

As such, embodiments of the present disclosure include techniques for improved calculation of filter outputs to provide the filter output with a reduced latency relative to linear and/or parallel processing of filter stages, while maintaining signal quality and/or without increasing the processing rate. In some embodiments, filter circuitry may include a filter block with a number of filter stages, each stage having one or more filter components such as multipliers, adders, phase delays, and/or sub-filters (e.g., groupings of components), such as all-pass filters, low-pass filters, high-pass filters, etc. For example, the filter block may be or include a finite impulse response (FIR) filter, a sparse FIR filter, a warped FIR filter, an infinite impulse response (IIR) filter, bi-quad filter, cascaded bi-quad filter, and/or any linear, time-invariant filter or system of filters. Additionally, by defining coefficients of the filter components (e.g., multiplier coefficients), the filter input may be modified to achieve a desired result, such as to generate a counteracting (e.g., inverse) audio signal corresponding to ambient noise represented by the input signal. Furthermore, in some embodiments, the filter stages of the filter block may be disposed in a direct form or disposed in a transpose form. For example, a direct form may perform calculations (e.g., multiplications, phase shifts, adds) for each filter stage and sum the outputs of each filter stage. In other words, in some embodiments, the direct form may include filters stages disposed in parallel relative to a series summation line of filter stage outputs. Moreover, in some embodiments, a transpose form may perform calculations of filter stages such that a portion of the filter stages are disposed in the series summation of filter stage outputs. As should be appreciated, the examples of direct and transpose forms discussed herein are given as examples and different filters of the filter block may include any distribution of filter components that form a linear time-invariant filter or system of filters.

As discussed herein, the filter circuitry may also include an early out block that computes an early out multiplier, indicative of the filter processing, and the early out offset, indicative of the accumulated state of the filter block to directly calculate the filtered signal based on the input signal before or without evaluating the computations of the individual filter stages. In other words, the early out block may determine a filtered signal of the filter block without or prior to evaluation of the filter block. For example, the early out block may directly calculate the output of the filter of the filter block by multiplying the filter input by an early out multiplier and adding an early out offset. Moreover, the multiply-add computation may generally be performed faster (e.g., in less computational cycles) than evaluation of the filter stages, thus providing a latency improvement. In some embodiments, the early out multiplier may be determined based on a combination of the filter coefficients (e.g., multiplier coefficients) of the components of the filter block. Additionally, the early out offset may be determined based on an accumulated state of the filter block from a previous filter input. For example, the accumulated state of the filter block may be based on calculated values at one or more of the filter stages (e.g., at intermediate points within the filter block). Additionally, in some embodiments, the early out block may operate in parallel with the filter block. For example, the early out block may directly calculate the filtered signal based on the input signal, the filter coefficients, and the accumulated state of the previous filter cycle, providing the filtered signal, while the filter block is evaluating the filter stages to obtain the accumulated state of the filter block for use by the early out block with the next filter input.

Additionally, in some embodiments, a coefficient adaptation block of the filter circuitry may update or otherwise change the coefficients of the filter components (e.g., multiplier coefficients) to make corrections and/or changes to the effect of the filter on the input signal. For example, in the case of noise cancelation, while a first microphone receives ambient noise, a second microphone may be implemented at the output (e.g., speaker location) of the electronic device to receive a residual of the combined audio including the ambient noise and the counteracting (e.g., inverse) audio. The coefficient adaptation block may determine (e.g., based on the combined audio) an error associated with the phase, frequencies, and/or amplitudes of the counteracting audio and adjust the coefficients of the filter block based thereon to synchronize the ambient noise and the counteracting audio for improved cancelation. As discussed herein, the early out block may utilize the updated coefficients to calculate the early out multiplier, indicative of the filter processing, and the early out offset, indicative of the accumulated state of the filter block.

As should be appreciated, the techniques discussed herein may be applicable in any suitable electronic device for use on any suitable digital data, such as audio data, image data, communications data, etc. Moreover, while audio signals are discussed herein as examples of data to be filtered, it should be appreciated that such is merely given as an example scenario where latency may be of particular interest. Furthermore, while the techniques discussed herein may be implemented to reduce latency associated with a digital filter, the embodiments discussed herein may also be applicable in scenarios where latency is not of principle concern and, thus, may be traded for other processing costs. For example, the early out computation may be performed while a processing rate or data rate is reduced, thus saving power while reducing or maintaining latency and/or increasing or maintaining signal quality.

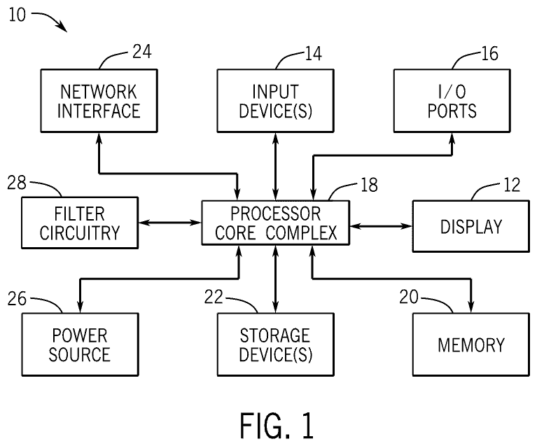

With the foregoing in mind, FIG. 1 is a block diagram of an electronic device 10 including an electronic display 12, that may utilize expedited filter calculation (e.g., via an early out block of filter circuitry) as discussed herein, according to embodiments of the present disclosure. As is described in more detail below, the electronic device 10 may be any suitable electronic device, such as a computer, a mobile phone, a portable media device, a tablet, a television, a virtual-reality headset, a wearable device such as a watch, a vehicle dashboard, earphones, a headset, or the like. Thus, it should be noted that FIG. 1 is merely one example of a particular implementation and is intended to illustrate the types of components that may be present in an electronic device 10.

The electronic device 10 may include an electronic display 12, one or more input devices 14, one or more input/output (I/O) ports 16, a processor core complex 18 having one or more processing circuits (circuitry) or processing circuitry cores, local memory 20, a main memory storage device 22, a network interface 24, a power source 26 (e.g., power supply), and/or filter circuitry 28. The various components described in FIG. 1 may include hardware elements (e.g., circuitry), software elements (e.g., a tangible, non-transitory computer-readable medium storing executable instructions), or a combination of both hardware and software elements. It should be noted that the various depicted components may be combined into fewer components or separated into additional components. For example, the local memory 20 and the main memory storage device 22 may be included in a single component. Moreover, the filter circuitry 28 may be implemented as standalone circuitry and/or combined with or integral with the processor core complex 18.

The processor core complex 18 is operably coupled with local memory 20 and the main memory storage device 22. Thus, the processor core complex 18 may execute instructions stored in local memory 20 and/or the main memory storage device 22 to perform operations, such as generating or transmitting image data to display on the electronic display 12. As such, the processor core complex 18 may include one or more processors, one or more general purpose microprocessors, one or more application specific integrated circuits (ASICs), one or more field programmable gate arrays (FPGAs), or any combination thereof. In some embodiments, a system on a chip (SoC) may include the processor core complex 18, among other things.

In addition to program instructions, the local memory 20 or the main memory storage device 22 may store data to be processed by the processor core complex 18. Thus, the local memory 20 and/or the main memory storage device 22 may include one or more tangible, non-transitory, computer-readable media. For example, the local memory 20 may include random access memory (RAM) and the main memory storage device 22 may include read-only memory (ROM), rewritable non-volatile memory such as flash memory, hard drives, optical discs, or the like.

The network interface 24 may communicate data with another electronic device or a network. For example, the network interface 24 (e.g., a radio frequency system) may enable the electronic device 10 to communicatively couple to a personal area network (PAN), such as a Bluetooth network, a local area network (LAN), such as an 802.11x Wi-Fi network, or a wide area network (WAN), such as a 4G, Long-Term Evolution (LTE), or 5G cellular network.

The power source 26 may provide electrical power to one or more components in the electronic device 10, such as the processor core complex 18 or the electronic display 12. For example, the power source 26 may include a power supply rail and/or a ground terminal coupled to the one or more components in the electronic device 10, such as the processor core complex 18 or the electronic display 12, to provide the electrical power. Thus, the power source 26 may include any suitable source of energy, such as a rechargeable lithium polymer (Li-poly) battery or an alternating current (AC) power converter.

The I/O ports 16 may enable the electronic device 10 to interface with other electronic devices. For example, when a portable storage device is connected, the I/O port 16 may enable the processor core complex 18 to communicate data with the portable storage device. The input devices 14 may enable user interaction with the electronic device 10, for example, by receiving user inputs via a button, a keyboard, a mouse, a trackpad, or the like. The input device 14 may include touch-sensing components in the electronic display 12. The touch sensing components may receive user inputs by detecting occurrence or position of an object touching the surface of the electronic display 12.

The electronic display 12 may display a graphical user interface (GUI) (e.g., of an operating system or computer program), an application interface, text, a still image, and/or video content. The electronic display 12 may include a display panel of any suitable type and include one or more display pixels to facilitate displaying images by controlling the luminance output (e.g., light emission) of the display pixels based on corresponding image data. Moreover, in some embodiments, the electronic device 10 may include multiple electronic displays 12 and/or may perform image processing for one or more external electronic displays 12, such as connected via the network interface 24 and/or the I/O ports 16.

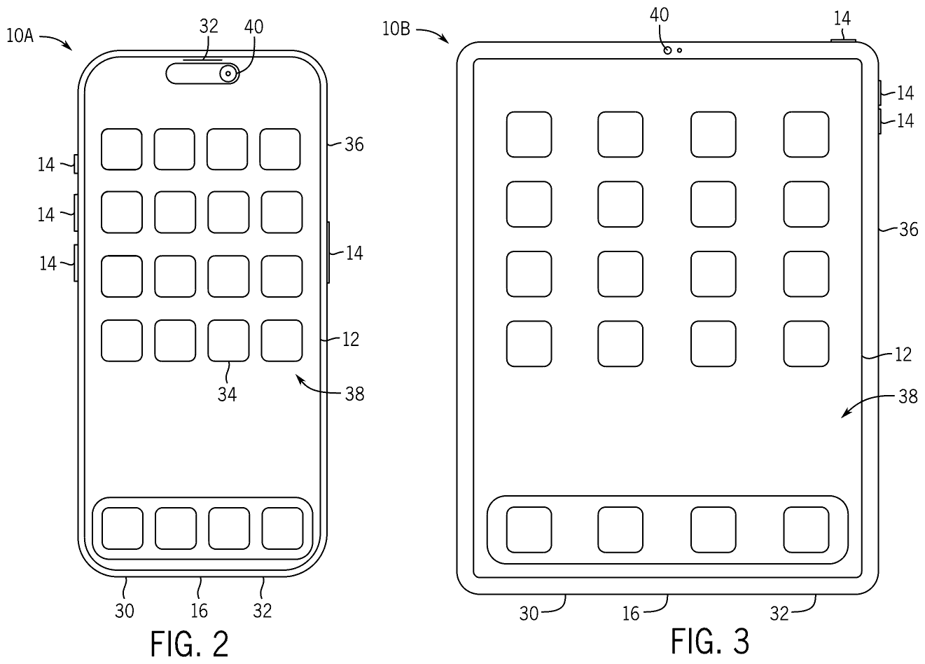

To help illustrate, an example of the electronic device 10, a handheld device 10A, is shown in FIG. 2. The handheld device 10A may be a portable phone, a media player, a personal data organizer, a handheld game platform, or the like. For illustrative purposes, the handheld device 10A may be a smart phone, such as any IPHONE® model available from Apple Inc.

In some embodiments, the input devices 14 may include one or more microphones 30 for receiving audio sounds. For example, a microphone 30 may convert audible sounds into electrical signals interpretable by the electronic device 10. Furthermore, speakers 32 may enable the electronic device 10 to convert electrical signals into audible sound. That is, the electronic device 10 may generate one or more audio signals and output the audio signal via the speakers 32. Thus, the speakers 32 may include components for amplifying and projecting sound to provide the audio output for various applications. Moreover, in some embodiments, one or more of the input devices 14 may be accessed through openings in an enclosure 36 (e.g., housing). The enclosure 36 may protect interior components from physical damage or shield them from electromagnetic interference, such as by surrounding the electronic display 12, processor core complex 18, microphone(s) 30, and/or speaker(s) 32. The input devices 14 may enable a user to interact with the handheld device 10A. For example, the input devices 14 may enable the user to activate or deactivate the handheld device 10A, navigate a user interface to a home screen, navigate a user interface to a user-configurable application screen, activate a voice-recognition feature (e.g., via a microphone 30), provide volume control, or toggle between vibrate and ring modes. For example, the electronic display 12 may display a graphical user interface (GUI) 38 having an array of icons. As such, when an icon 34 is selected either by an input device 14 or a touch-sensing component of the electronic display 12, an application program may launch. Additionally, the electronic device may include one or more cameras 40 to capture pictures or video. In some embodiments, a camera 40 may be used in conjunction with a virtual reality or augmented reality visualization on the electronic display 12.

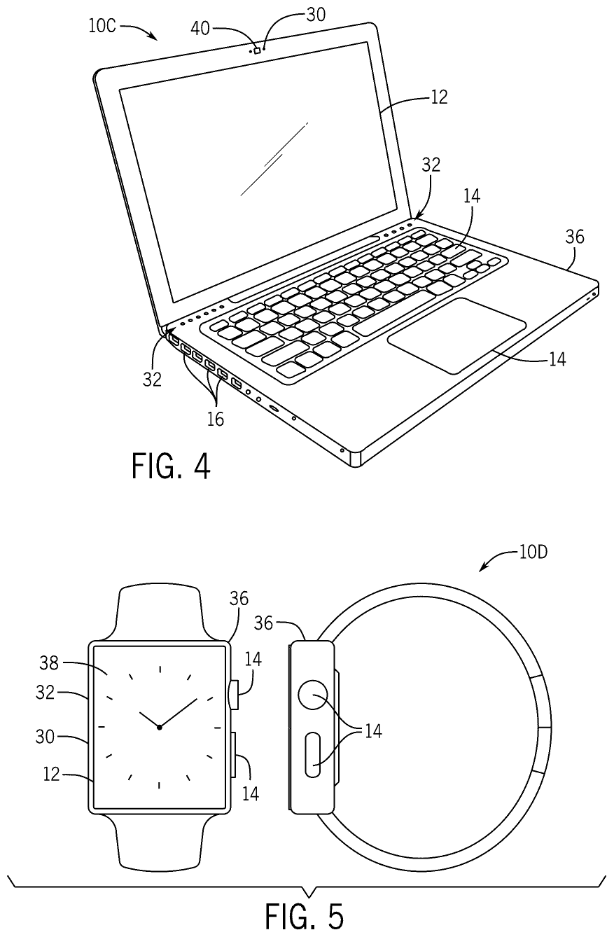

Another example of a suitable electronic device 10, specifically a tablet device 10B, is shown in FIG. 3. The tablet device 10B may be any IPAD® model available from Apple Inc. A further example of a suitable electronic device 10, specifically a computer 10C, is shown in FIG. 4. For illustrative purposes, the computer 10C may be any MACBOOK® or IMAC® model available from Apple Inc. Moreover, while the computer 10C is illustrated as a portable computer (e.g., notebook or laptop computer), the computer 10C may also be a desktop computer. Another example of a suitable electronic device 10, specifically a watch 10D, is shown in FIG. 5. For illustrative purposes, the watch 10D may be any APPLE WATCH® model available from Apple Inc.

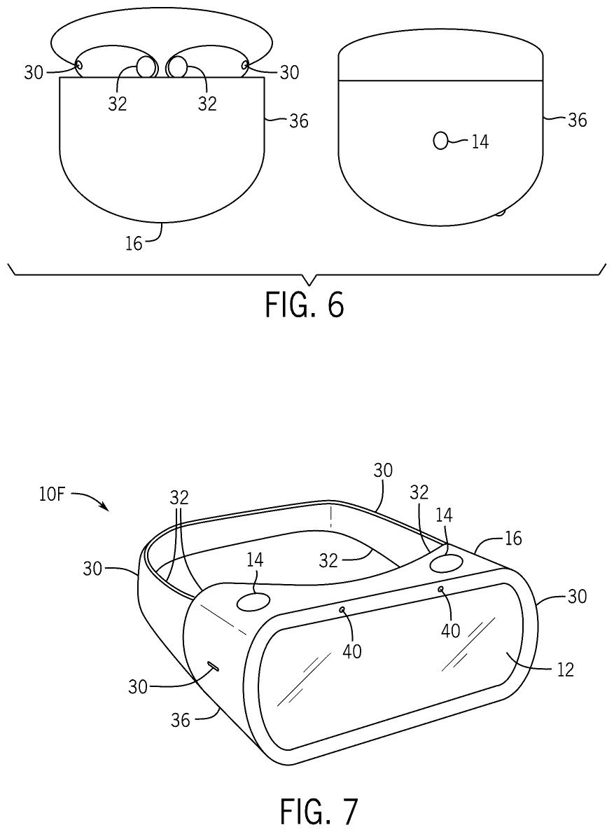

Another example of a suitable electronic device 10, specifically an audio device 10E, is shown in FIG. 6. For illustrative purposes, the audio device 10E may be any AIRPODS® model available from Apple Inc. Another example of a suitable electronic device 10, specifically a headset 10F (e.g., an extended reality (XR), mixed reality (MR), virtual reality (VR), and/or augmented reality (AR) headset), is shown in FIG. 7. For illustrative purposes, the headset 10F may be any VISION PRO® model available from Apple Inc.

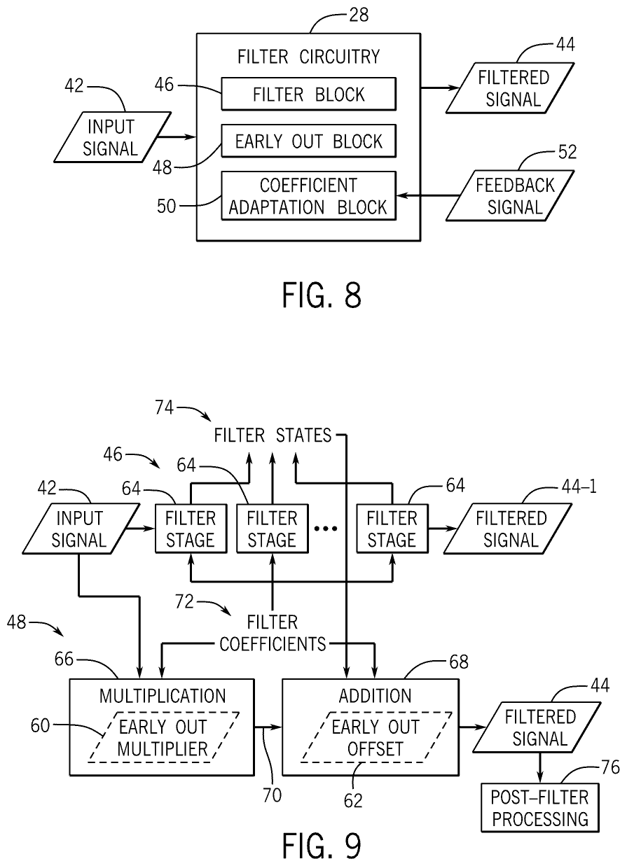

As discussed herein, the electronic device 10 may include filter circuitry 28 for digital signal processing (DSP) that receives an input signal 42 and generates a filtered signal 44, as shown in FIG. 8. In some embodiments, the filter circuitry 28 may include a filter block 46, an early out block 48, and a coefficient adaptation block 50. As discussed further below, the filter block 46 may include a linear time-invariant filter or linear time-invariant system of filters (e.g., a number of filters in series or parallel), each having one or more filter stages for performing DSP on an input signal 42. Furthermore, in some embodiments, the coefficient adaptation block 50 may provide changes (e.g., based on a feedback signal 52 and/or setting of the electronic device 10) to filter coefficients (e.g., multiplier coefficients) of the filter block 46 to alter the effect of the filter block 46 on the input signal 42. Furthermore, the early out block 48 may provide an expedited output of the filtered signal 44, relative to traditional evaluation of the filter of the filter block 46.

As should be appreciated, although the filter circuitry 28 is discussed herein as including a number of blocks, embodiments may include hardware and/or software components to carry out the techniques discussed herein. Moreover, while the term “block” is used herein, there may or may not be a logical or physical separation therebetween. Furthermore, in some scenarios, the input signal 42 may be a continuous stream (e.g., over a period of time) of data, such as a microphone feed of audio data, a camera feed of image data, a communication transmission, etc., and may be sourced in any suitable way (e.g., generated by the electronic device 10, captured via a camera 40 or microphone 30, fetched from a memory 20/storage device 22, received via an I/O port 16, or received via network interface 24). Furthermore, the filtered signal 44 may be a corresponding adaptation of the input signal, such as a noise cancelation signal (e.g., an inverse of the input signal 42), an augmented image data signal, or the like. Moreover, in some embodiments, the filtered signal 44 may be indicative of a statistical analysis of the input signal 42. As should be appreciated, while discussed herein in the context of an audio, video, or communication signal (e.g., input signal 42) the present techniques of the early out block 48 may be applicable for any suitable input signal 42 and any suitable filter block 46.

In some scenarios, it may be desirable to utilize one or more filters (e.g., for DSP) while conforming to one or more constraints, such as latency, signal quality, and computational costs (e.g., circuitry footprint, power consumption, and/or computational complexity). For example, the electronic device 10 may perform noise canceling that requires the filtered signal 44 to be output (e.g., via a speaker 32) in sync with environmental noise, resulting in a time constraint for processing the filtered signal 44. Furthermore, while operating a digital filter at a higher processing rate and/or on a reduced-bit signal may also provide reduced latency, such may also be associated with increased power consumption and/or reduced quality. As such, techniques for obtaining a filtered signal 44 in less time without sacrificing quality or increasing processing speed may be of particular benefit.

To this end, the filter circuitry 28 may include an early out block 48 that computes an early out multiplier 60 (e.g., multiplier factor), indicative of the filter processing, and an early out offset 62 (e.g., addition offset), indicative of the accumulated state of the filter block 46 to directly calculate the filtered signal 44 based on the input signal 42 before or without evaluating the computations of the individual filter stages 64, as shown in FIG. 9. For example, the filtered signal 44 may be computed via the early out block 48, foregoing full computation of the filtered signal 44-1 via the filter block 46. As should be appreciated, while the filtered signal 44 computed by the early out block 48 is the same value as the filtered signal 44-1 of the filter block 46, providing the filtered signal 44 via the early out block 48 may realize improvements in the way DSP (e.g., via a processor and/or digital circuitry) is performed, such as improved latency. In some embodiments, the early out block 48 may directly calculate the filtered signal 44 of the filter block 46 by a multiplication 66 (e.g., multiplying the input signal 42 by the early out multiplier 60) and an addition 68 (e.g., adding the early out offset 62 to the multiplied signal 70). This expedited calculation may be performed by exploiting properties of linear time-invariant filters to rearrange and factorize the effective processing of the filter block 46 as a change to the input signal 42 in combination with an effect of previous input signals 42. For example, the filter block 46 may include a number, n, of filter stages 64 (e.g., tap points), each having one or more filter components (e.g., adders, multipliers, phase shifts) defined with respective filter coefficients 72. By leveraging the effect of phase shifts (e.g., z-inverse functions), as delaying the flow of data through the filter block 46 by a cycle, portions of the filter stages 64 that rely upon phase delayed outputs of previous filter stages 64 may be separated out from calculations that rely upon the current input signal 42. In other words, as the input signal 42 will be delayed at certain filter components by a cycle, the effect of such components on the filtered signal 44 for the current cycle (e.g., current sample of the input signal 42) will not be based on the input signal 42 and may be precomputed based on the filter states 74 of the previous input signal 42 (e.g., previous sample of the input signal 42). As such, the early out offset 62 may be precomputed (e.g., prior to receiving the current input signal 42) based on an aggregate of the filter states 74 generated by the previous input signal 42 and the filter coefficients 72. Furthermore, components of the filtered signal 44 that do not cause a phase delay and/or are not blocked by a data path with a phase delay may be effectively combined to form a single multiplier (e.g., the early out multiplier 60) to be applied to the input signal 42. As such, the early out multiplier 60 may be precomputed (e.g., prior to receiving the current input signal 42) based on the filter coefficients 72 without deference to the current filter states 74.

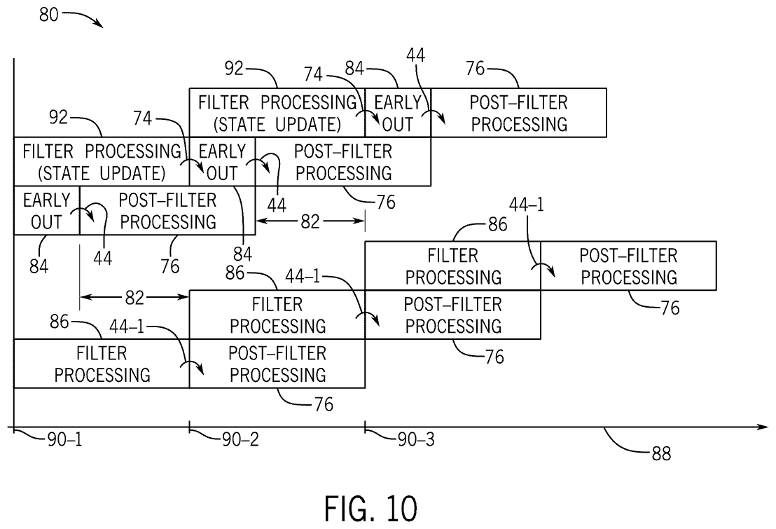

As should be appreciated, a multiply-add computation of the early out block 48 may be performed faster (e.g., in less computational cycles) than sequential evaluation of the filter stages 64, thus providing a latency improvement. Furthermore, in some embodiments, the computation of the early out multiplier 60 and/or early out offset 62 for the next input signal 42 may be performed during (e.g., in parallel with) the multiply-add calculation of the early out block 48 and/or one or more aspects of post-filter processing 76, such as for additional realization of the latency improvement. To help illustrate, FIG. 10 is a timing diagram 80 illustrating an example latency improvement 82 of the early out computation 84 (e.g., multiply-add calculation) over filter processing 86 (e.g., evaluation of filter stages 64) through three samples of the input signal 42. As should be appreciated, the timing diagram 80 is shown as an illustrative tool and is not intended to be to scale in time 88. In some embodiments, receptions 90 (e.g., first reception 90-1, second reception 90-2, and last reception 90-3, cumulatively 90) of individual samples of the input signal 42 may be processed via an early out computation 84 to provide the filtered signal 44 earlier (e.g., by the latency improvement 82) than filter processing 86 would provide the filtered signal 44-1 at the same sampling rate (e.g., data quality). In other words, for each sample period (e.g., reception 90), the filtered signal 44, and therefore post-filter processed signal, may be determined and output sooner than it would have with filter processing 86.

Additionally, in conjunction with the early out computation 84, at least a portion of the filter processing 86 (e.g., state update filter processing 92) may be performed to determine the filter states 74, such as to compute the early out offset 62 for use in the early out computation 84. Furthermore, the filter block 46 may include circuitry for and/or a digital model of the full set of filter components or include only a subset thereof for computing the filter states 74. For example, in some embodiments, instead of digitally representing the filter components in a direct form or transpose form, the filter block 46 may only calculate the filter states 74 for calculating the early out offset 62. In other words, the filter block 46 may model the filter states 74 instead of the full set of filter components. Thus, the filter block 46 may not model and/or evaluate the entirety of the filter components that would be necessary for filter processing 86 to generate the filtered signal 44-1.

The state update filter processing 92 and/or early out computation 84 may be performed in parallel with post-filter processing 76, such as digital-to-analog conversion, further filtering and/or modulation to name a few. In some embodiments, the first reception 90-1 of the input signal 42 may be processed via the early out computation 84 without performing state update filter processing 92 beforehand. Indeed, as discussed above, the early out offset 62 may be a function of the previous filter state 74, which, for the first reception 90-1, may have no contribution. Furthermore, state update filter processing 92 may be foregone for the last reception 90-3, as there would be no next sample on which to perform the early out computation 84.

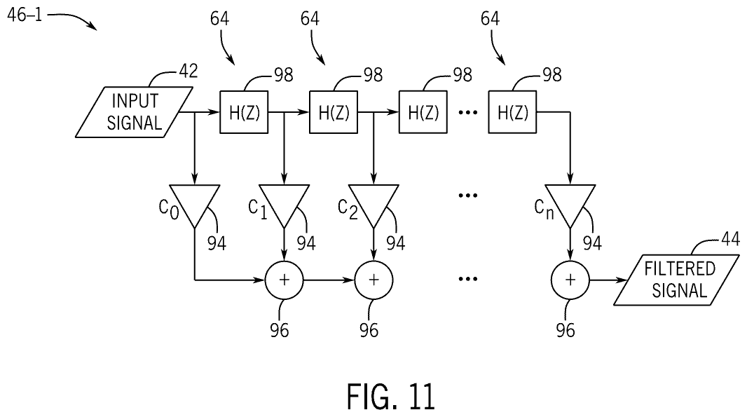

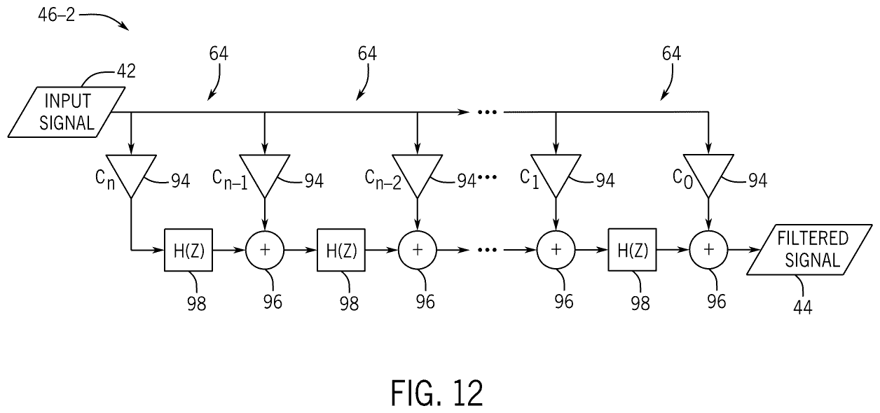

As discussed above, the early out multiplier 60 may be determined based on a combination of the filter coefficients 72 (e.g., multiplier coefficients) of the filter components of the filter block 46, and the early out offset 62 may be determined based on an accumulated state (e.g., filter states 74 of the filter stages 64) of the filter block 46 from a previous input signal 42. Furthermore, as used herein, the filter block 46 may include any linear time-invariant filter or linear time-invariant system of filters (e.g., a number of filters in series or parallel), each having one or more filter stages 64 for performing DSP on an input signal 42. To help illustrate, FIG. 11 is a schematic diagram of an example filter block 46-1 having multiple filter stages 64 disposed in a direct form, and FIG. 12 is a schematic diagram of an example filter block 46-2 having multiple filter stages 64 disposed in a transpose form. As discussed herein, the filter block 46 may include one or more filter stages 64 of one or more filter components such as multipliers 94, adders 96, and transfer functions 98 (e.g., H(z) functions). As discussed above, transfer functions 98 introduce phase delays (e.g., cycle delays in the data path of the input signal 42) such that at least a portion of the transfer function 98 output is based on a previous state (e.g., filter state 74) from one or more previous input signals 42. As such, the filter block 46 may be considered as having a portion attributable to previous filter states 74 and a portion attributable to the current input signal 42.

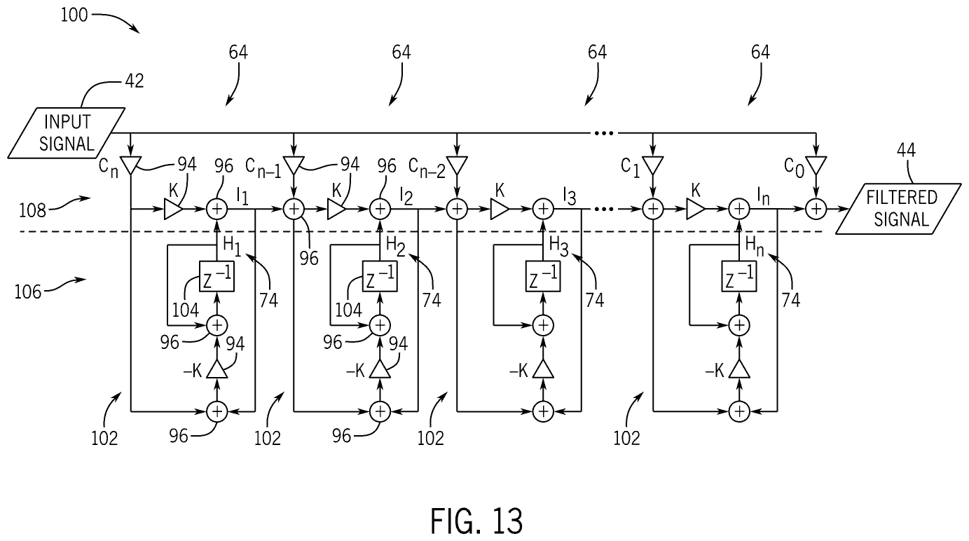

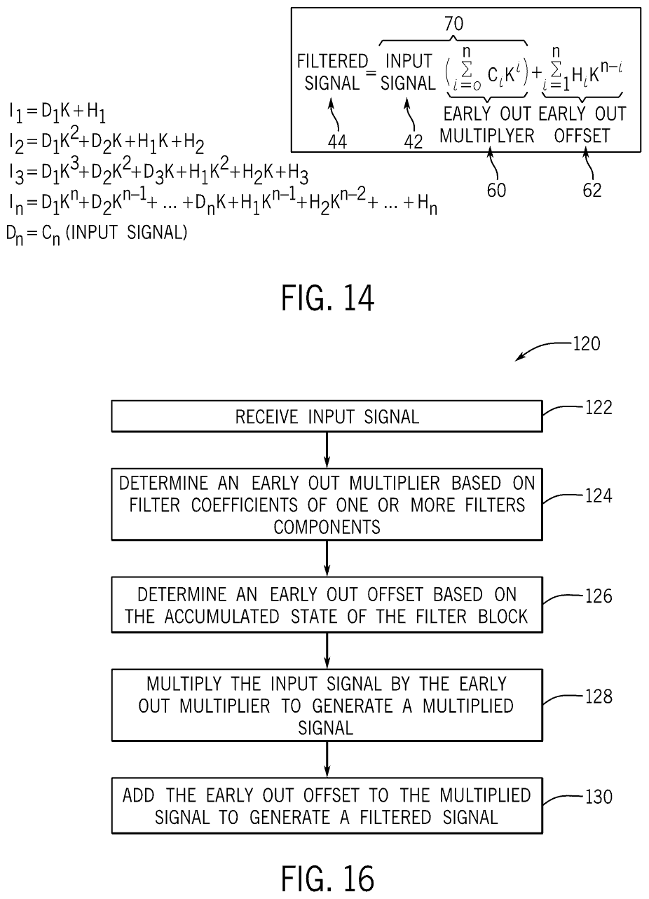

As a non-limiting example, the transfer function 98 may correspond to an all-pass filter such that the filter block 46 forms a warped FIR filter 100, as shown in FIG. 13. In the depicted example, the warped FIR filter 100 includes multipliers 94, with corresponding coefficients, Cₙ, adders 96, and all-pass filters 102. Each all-pass filter includes a phase delay 104 (e.g., z-inverse), multipliers 94 with corresponding coefficients, K and −K, as well as adders 96. In general, the phase delay 104 may be represented by a z-inverse function, Z^{-m}, where “m” is a number of cycle delays. For example, a phase delay 104 of Z⁻⁴ may represent a phase delay of four cycles. As discussed herein, the transfer function 98 (e.g., all-pass filter 102), in combination with the other filter components, may be represented by a delayed portion 106 and a current portion 108. The current portion 108, in-line with the input signal 42 may be reduced to a combination of number of the filter coefficients 72 and the delayed portion 106 may be reduced to previously computed filter states 74 (e.g., Hᵢ), such as from previous state update filter processing 92. FIG. 14 is a graphical depiction of an example early out computation 84 corresponding to the warped FIR filter 100 of FIG. 13 including intermediate calculations (e.g., of intermediate values), Iᵢ, for outputs of each filter stage 64. In the depicted example, the values of the intermediate multipliers and previously computed filter states 74 may be combined and factored into a multiplied signal 70 (e.g., input signal 42 multiplied by the early out multiplier 60) plus the early out offset 62. As should be appreciated, the warped FIR filter 100 is merely given as an example filter block 46 and any linear time-invariant filter or filter system may be arranged or otherwise represented by portions attributable to the current input signal 42 and previous input signals 42.

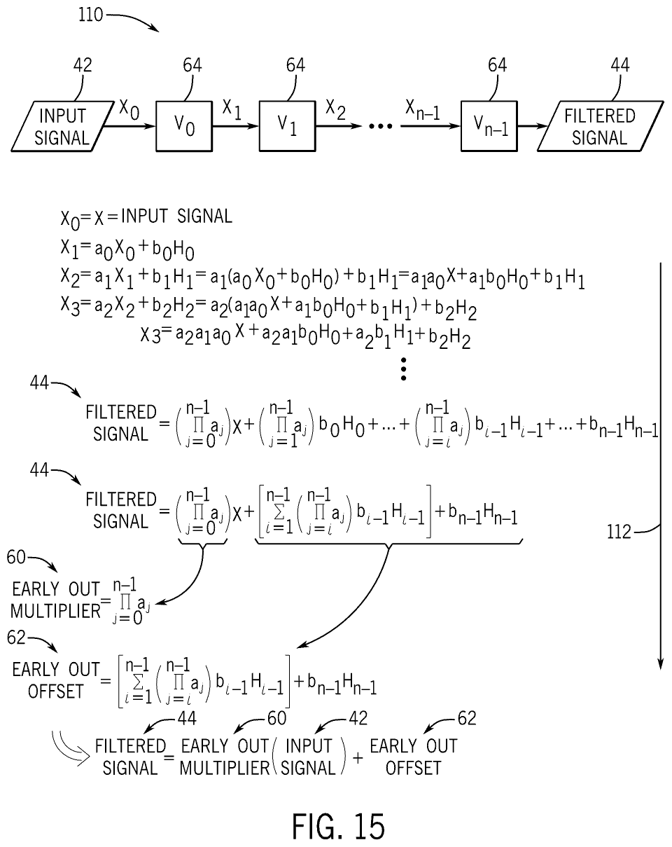

As discussed above, a filter block 46 may include a number of filter stages 64 that utilize filter coefficients 72 and/or transfer functions 98 to filter an input signal 42 and generate the filtered signal 44. Moreover, as discussed above, the techniques provided herein may be applicable to any linear time invariant filter system. Moreover, each filter stage 64 may be the same or different from the other filter stages 64. To help further illustrate, FIG. 15 is a schematic diagram of a genericized filter 100 of the filter block 46 having a cascaded chain of filter stages 64, Vᵢ, along with a graphical depiction of an example early out computation. For example, each filter stage 64, Vᵢ, may be expressed as a linear combination of its input, xᵢ, and one of its states, Hᵢ. As such, provided the techniques discussed herein, the calculation of the filtered signal 44 may be condensed (as shown by arrow 112) to a multiplication of the input signal 42 by an early out multiplier 60, indicative of properties of the filter stages 64, and an early out offset 62 indicative of the previous states of the filter stages 64.

FIG. 16 is a flowchart of an example process 120 for implementing an early out block 48 of filter circuitry 28 to generate expedite computation of a filtered signal 44. The filter circuitry may receive the input signal 42 (process block 122). Additionally, the filter circuitry 28 (e.g., via an early out block 48) may determine an early out multiplier 60 based on the filter coefficients 72 of a filter block 46 of the filter circuitry 28 (process block 124). As should be appreciated, the early out multiplier 60 may be precomputed (e.g., before receiving the input signal 42 based on the filter coefficients 72 and maintained and utilized for use with multiple input signals 42. Moreover, the early out multiplier 60 may be recalculated in response to changes in the filter coefficients 72, such as by the coefficient adaptation block 50, to change the effect of the filter on the input signal 42. Additionally, the filter circuitry 28 may determine an early out offset 62 based on the accumulated/aggregated state (e.g., aggregation of filter states 74) of the filter block 46 (process block 126). Additionally, the input signal 42 may be multiplied by the early out multiplier 60 to generate a multiplied signal 70 (process block 128), and the early out offset 62 may be added to the multiplied signal 70 to generate a filtered signal 44 (process block 130).

As such, in accordance with aspects of the present disclosure, filter circuitry 28 may include an early out block 48 to reduce the latency associated with DSP of a linear time-invariant filter. Furthermore, while the techniques discussed herein may be implemented to reduce latency associated with a digital filter, the embodiments discussed herein may also be applicable in scenarios where latency is not of principle concern and, thus, may be traded for other processing costs. For example, the early out computation may be performed while a processing rate or data rate is reduced, thus saving power while reducing or maintaining latency and/or increasing or maintaining signal quality. Furthermore, although the flowchart discussed above is shown in a given order, in certain embodiments, process blocks may be reordered, altered, deleted, and/or occur simultaneously. Additionally, the flowchart is given as illustrative tool and further decision and process blocks may also be added depending on implementation.

It is well understood that the use of personally identifiable information should follow privacy policies and practices that are generally recognized as meeting or exceeding industry or governmental requirements for maintaining the privacy of users. In particular, personally identifiable information data should be managed and handled so as to minimize risks of unintentional or unauthorized access or use, and the nature of authorized use should be clearly indicated to users.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function]. . . ” or “step for [perform]ing [a function]. . . ”, it is intended that such elements are to be interpreted under 35 U.S.C. 112(f). However, for any claims containing elements designated in any other manner, it is intended that such elements are not to be interpreted under 35 U.S.C. 112(f).

1. An electronic device comprising:
a first portion of filter circuitry configured to model at least a portion of a digital filter for an input signal; and
a second portion of the filter circuitry configured to generate a filtered signal corresponding to an application of the digital filter on the input signal, wherein the second portion of the filter circuitry is configured to generate the filtered signal based on:
determining a multiplication factor based on respective filter coefficients of filter components of the digital filter;
determining an addition offset based on an aggregated state of the digital filter modeled by the first portion of the filter circuitry; and
combining the multiplication factor, the addition offset, and the input signal.

2. The electronic device of claim 1, wherein combining the multiplication factor, the addition offset, and the input signal comprises:
multiplying the input signal by the multiplication factor to generate a multiplied signal; and
adding the addition offset to the multiplied signal to generate the filtered signal.

3. The electronic device of claim 1, wherein the digital filter is a linear time-invariant filter.

4. The electronic device of claim 3, wherein the digital filter comprises a finite impulse response (FIR) filter, one or more all-pass filters, a bi-quad filter, or any combination thereof.

5. The electronic device of claim 3, wherein the input signal comprises a digital video signal or a digital audio signal.

6. The electronic device of claim 1, wherein filtering the input signal via the digital filter at a processing rate would take a first amount of time, and wherein generating the filtered signal via the second portion of the filter circuitry at the processing rate takes a second amount of time, wherein the second amount of time is less than the first amount of time.

7. The electronic device of claim 1, wherein the aggregated state is based on one or more previous input signals and the respective filter coefficients.

8. The electronic device of claim 7, wherein the aggregated state is based on an output of a phase delay of a transfer function of the digital filter.

9. The electronic device of claim 1, wherein the second portion of the filter circuitry is configured to determine the multiplication factor and the addition offset before the filter circuitry receives the input signal.

10. The electronic device of claim 1, wherein a third portion of the filter circuitry is configured to determine changes to the respective filter coefficients to change an effect of the digital filter on the input signal, wherein the second portion of the filter circuitry is configured to recalculate the multiplication factor in response the changes to the respective filter coefficients.

11. Filter circuitry configured to:
model at least a portion of a digital filter;
determine a multiplication factor based on respective filter coefficients of filter components of the digital filter;
determine an addition offset based on the respective filter coefficients;
receive an input signal;
combine the multiplication factor, the addition offset, and the input signal to generate a filtered signal, wherein the filtered signal is equivalent to processing the input signal through the digital filter; and
output the filtered signal.

12. The filter circuitry of claim 11, wherein the filter circuitry is configured to determine the addition offset based on an aggregated state of the digital filter, wherein the portion of the digital filter comprises the aggregated state of the digital filter.

13. The filter circuitry of claim 12, wherein the aggregated state of the digital filter is based on intermediate values of the digital filter at tap points within the digital filter, and wherein the intermediate values of the digital filter are based on one or more previous input signals.

14. The filter circuitry of claim 11, wherein combining the multiplication factor, the addition offset, and the input signal comprises:
multiplying the input signal by the multiplication factor to generate a multiplied signal; and
adding the addition offset to the multiplied signal to generate the filtered signal.

15. The filter circuitry of claim 11, wherein the input signal is indicative of an environment audio sound and the filtered signal is indicative of an inverted audio sound, wherein the filter circuitry is configured to:
receive a feedback signal indicative of residual sound comprising a summation of the environment audio sound and the inverted audio sound; and
adjust one or more coefficients of the respective filter coefficients based on the feedback signal.

16. The filter circuitry of claim 11, wherein the digital filter comprises a warped finite impulse response (FIR) filter, the warped FIR filter comprising a plurality of all-pass filter stages disposed in a transpose form.

17. A non-transitory, machine-readable medium comprising instructions, wherein, when executed by one or more processors, the instructions cause the one or more processors to control operations of filter circuitry or to perform the operations, the operations comprising:
modeling at least a portion of a digital filter;
determining a multiplication factor based on respective filter coefficients of filter components of the digital filter;
determining an addition offset based on the respective filter coefficients;
receiving an input signal;
multiplying the input signal by the multiplication factor to generate a multiplied signal;
adding the addition offset to the multiplied signal to generate a filtered signal, wherein the filtered signal is equivalent to processing the input signal through the digital filter; and
outputting the filtered signal.

18. The non-transitory, machine-readable medium of claim 17, wherein the operations comprise determining the multiplication factor and determining the addition offset before receiving the input signal.

19. The non-transitory, machine-readable medium of claim 18, wherein the addition offset if based on one or more previous input signals, and wherein the multiplication factor is not based on the one or more previous input signals.

20. The non-transitory, machine-readable medium of claim 17, wherein the filter circuitry is configured to determine the addition offset based on an aggregated state of the digital filter, wherein the portion of the digital filter comprises the aggregated state of the digital filter.
